(19) United States
(12) Patent Application Publication
(10) Pub. No.: US 2010/0230151 A1
(43) Pub. Date: Sep. 16, 2010

(54) Circuit layout and method and device for producing a circuit pattern on a substrate

(76) Inventor: Manfred Michalk, Erfurt (DE)

Correspondence Address: Muncy, Geissler, Olds & Lowe, PLLC, 4000 Legato Road, Suite 310, FAIRFAX, VA, 22033, US

(21) Appl. No.: 12/659,375

(22) Filed: Mar. 5, 2010

(30) Foreign Application Priority Data
Mar. 7, 2009 (DE) 10 2009 012 255.9

(51) Int. Cl. H05K 1/16; H05K 3/00

(52) U.S. Cl. 174/260; 29/829; 29/739

(57) ABSTRACT

A circuit layout having a substrate with at least one electronic component, wherein contacts of the electronic component are electrically connected to contacting regions of a conductor strip. Furthermore, a method for producing a circuit pattern is provided, whereby at least one conductor strip is attached onto at least one surface side of the substrate, the conductor strip being coated with a meltable insulating varnish and whereby the insulating varnish is heated and the conductor strip is pressed onto the substrate. A device is also provided for producing a circuit pattern comprising a conductor strip coil and a cylindrical or conical laying tool, which at least over a part of its length has an interior bore guiding the conductor strip and an annular active area arranged perpendicular to its longitudinal axis and merging in inner and outer radius.

The invention relates to a circuit layout comprising a substrate with at least one electronic component and a method for producing a circuit pattern on a substrate. Furthermore, the invention relates to a device for producing a circuit pattern on a substrate according to the features of the preamble of claim 14.

From the prior art semi-finished products are already known for the production of security documents, such as, for example, smart cards, credit cards, electronic personal identity documents or electronic health cards. Semi-finished products of this type are so-called prelaminates or functional prelaminates, for example, which have as a circuit semiconductor chips, antennas and optionally further circuit elements. The functional prelaminates are mainly composed of one or more substrate films and two or more cover films on both sides of the substrate film or the substrate films. The films are mostly composed of thermoplastic materials such as polycarbonate (PC), polyethylene terephthalate (PET), polyvinyl chloride (PVC) and similar plastics.

In particular for producing electronic security cards, which have to have a very long service life and a very high security against tampering, it is necessary to produce the security cards such that an unnoticed removal and alteration of the chip is impossible. On the other hand, the security cards must have a high mechanical stability, so that after at least ten years of use of the cards, no cracks or kinks or a defect in the electronic circuit occur. Furthermore, the security card or smart card must guarantee a very high quality of the glossy surfaces of the card after lamination or adhesion of the substrate or the prelaminate with other films.

The preferred material for the production of electronic security cards is polycarbonate. Polycarbonate has a high mechanical stability and is temperature-resistant up to a temperature of approx. 130° C. PET exhibits similar qualities. In the production of the prelaminates, however, the high thermal elongation coefficient and the marked shrinkage of the materials have a negative effect on the quality of the laminate. The level of the processing temperature and the duration thereof thereby have an impact on the actual shrinkage. Furthermore, the material has a relatively small softening range (compared to PVC). Temperature fluctuations during prelamination lead to significant differences in the viscosity and thus to more or less marked inflow of construction-related through holes in the core films or the substrate film. After the prelamination and/or final lamination, shrinkage and material contraction have an effect such that considerable mechanical stresses around the electronic modules, the circuit wires (antennas) and at the connecting points thereof occur, since the electronic modules and antenna wires located in the interior of the card do not shrink and do not contract substantially during cooling. Several unfavorable effects are associated with this:

Around the modules (semiconductor chip, lead frame and casting) the mechanical stresses in the polycarbonate are so high that after bending strains and/or alternating temperature tests of the cards cracks are shown in the surrounding polycarbonate, which cracks gradually spread over further areas of the card. On the other hand, the module and in part also the circuit wire (in the case of contactless smart cards, the antenna wire) are clearly imaged on the glossy surface of the security cards. The mechanical stresses acting on the module furthermore exert shear effects on the connecting points of circuit wire to module and reduce the reliability of the security cards.

In DE 197 10 656 A1 a smart card is disclosed, wherein the films have recesses to accommodate the components such as antenna coil or chip module or other electronic components. The components are embedded in the recesses into a liquid filler. The excess filler is then removed. Subsequently, the setting of the filler and the lamination of the layers occur.

In WO 2007/089140 A1 an identity document is disclosed in which a rubber-like material that has a higher expansion coefficient than the adjoining laminate layers is arranged around the chip.

In US 2008/0179404 A1 a method and a device for the production of transponder inlays are described. A transponder chip module is recessed into a surface of a substrate. End portions of an antenna wire are held by means of a patch on terminal areas of the chip module, wherein the patch can be transparent in order to render possible laser bonding of the antenna wire to the terminal areas. The substrate as well as the transponder chip module arranged thereon and the antenna wire can be covered by a cover. A conductive glue or a solderable material can be used to connect the antenna wire to the terminal areas. The recess for the chip module and a channel for the antenna wire can be formed in the substrate by means of laser ablation. The substrate can be Teslin™, PET/PETE or polycarbonate. The antenna wire can have a diameter of 60 μm. A synthetic cushion material can be arranged under the transponder chip material.

From U.S. Pat. No. 6,665,931 B2 a wiring method is known for applying connecting wire to a substrate board. The connecting wire is applied onto the substrate by a three-dimensional relative movement between a wiring head that guides the wire and the substrate. The wiring head moves along an adhesive layer on the surface of the substrate. The wiring head and the adhesive layer intermittently come close to one another for point contact.

In DE 196 19 771 A 1, a method and a device for laying a wire conductor on a substrate as well as substrates produced therewith are described. A wire-shaped conductor is laid on a substrate by means of a laying device acting on the wire conductor with ultrasound, wherein the wire conductor is acted on with ultrasound in a direction transverse to the laying plane and the transverse movement of the laying device produced by the ultrasound impingement is superimposed on the laying movement running in the laying plane.

From DE 44 10 732 A 1 a method for producing a chip card and a chip card are known. In the method for producing a transponder unit, in particular a chip card, having at least one chip and one coil, the chip and the coil are arranged on a common substrate and the formation of the coil is carried out by laying a coil wire and the connection of coil wire ends with contact surfaces of the chip on the substrate.

In DE 198 40 220 A1 a transponder module and a method for producing the same are described. A transponder module, in particular for an electronic label, comprises a layer composed of an insulating material, which layer is provided as the only carrier substrate. An antenna device is formed on a first main surface of the carrier substrate. In a recess of the carrier substrate an unhoused circuit chip is arranged such that a first main surface of the circuit chip is essentially flush to the first main surface of the first carrier substrate. Electric connection devices between the circuit chip and the antenna device are provided. This transponder module has an extremely small thickness. A plurality of methods can be used to produce a transponder module of this type.

From DE 199 20 593 B4 a chip holder for a chip module and a method for producing the chip module are known. A chip holder for embodying a chip module has a substrate and connection leads arranged on the substrate. The connection leads are embodied in a strip-shaped manner and extend over the substrate parallel to one another. The connection leads are composed of electrically conductive connection strands applied onto the substrate and independent from the substrate in their embodiment. The substrate is formed by a carrier film. The connection strands are provided at least in some sections with a connecting material coating for contacting with the contact metallizations of a chip.

DE 41 15 421 A 1 describes a system for contactless automated strip bonding. A device for producing an interface to a device that has a plurality of conductors spaced apart close to one another has a first dielectric device for insulation with a first side and a second side and a first signal conductor device for electrical coupling, which device is connected to the first side of the dielectric device. Furthermore, the device has a first signal interference minimization device for reducing electric interference, which is coupled to the second side of the first dielectric device. The first signal interference minimization device contains a first signal minimization conductor for electric coupling, which does not go through the first dielectric device.

From DE 6 608 316 U an arrangement is known for welding parts provided with insulation by means of welding electrodes. At least one of the electrodes is provided with a heating device that is independent of the welding unit.

In US 2008/0143534 A 1 an apparatus and a method for producing an antenna for a radio frequency identifying device are described. The device for producing an antenna for wire transponders of electrically conducting material comprises at least one depositing device for depositing the wire on the substrate, which is placed on a support element. The depositing unit and the substrate can be moved relative to one another. The support element can be moved parallel to at least two axes of a Cartesian reference system. In a method for producing the antenna, a layer or a wire of electrically conductive material is unwound from at least one reel and pressed onto a surface of a substrate by means of at least one pressing element, fixed and the fixed layer or the fixed wire is separated from the layer or the wire on the reel by at least one cutting unit. The substrate can be moved relative to the arrangement, which comprises the reel, the pressing element and the cutting unit, parallel to at least one axis of a Cartesian reference system.

A further method is to reduce the volume of the conductor wires and the module and thus to reduce the mechanical stresses in the polycarbonate. Printed conductor paths are used as an antenna, onto which conductor paths the chip is directly bonded by means of a flip chip bonding method. One factor increasing costs is the high silver price of the print paste and the necessary curing temperature and curing time of the print paste, which in turn leads to a shrinkage of the printed film. In order to protect the film during prelamination, a further film is to be laminated onto the component-carrying substrate film, which further film has through holes for the accommodation of the chip already bonded. In order to avoid shear stresses between the substrate film and the protective film during prelamination by different shrinkage, the protective film must also be subjected to approximately the same temperature treatment beforehand as the printed substrate film; the shear stresses in addition can lead to bending of the prelaminates.

The object of the invention is to disclose a circuit layout that is improved compared to the prior art as well as an improved method for producing a circuit pattern on a substrate and an improved device for producing a circuit pattern on a substrate.

The object is attained according to the invention through a circuit layout comprising a substrate with at least one electronic component, with the features of claim 1, a method for producing a circuit pattern on a substrate with the features of claim 6 and a device for producing a circuit pattern on a substrate with the features of claim 14.

Advantageous embodiments of the invention are the subject matter of the subordinate claims.

A circuit layout comprises a substrate with at least one electronic component. According to the invention, at least one metallic electrically conductive conductor strip is arranged on and/or in the substrate in a twist-free manner in a circuit pattern, wherein contacts of the electronic component are electrically connected to contacting regions of the conductor strip.

The term conductor strip means an electric conductor embodied in a strip-shaped manner, the width of which is at least four times its thickness.

Preferably, the width of the conductor strip is ten times to one hundred times its thickness.

Advantageously, the conductor strip has a thickness of at least 5 μm.

Preferably, the conductor strip has a width of 0.2 mm to 1 mm, particularly preferably 0.25 mm to 1 mm and a thickness of 10 μm to 50 μm.

The conductor strip is arranged on and/or in the substrate in a straight or circular arc-shaped manner in predetermined radii and free of kinks.

The conductor strip thus has with comparable capacity a much smaller thickness than wire of the same cross section and can be attached well to the substrate or embedded well into the substrate. The conductor strip can be contacted and adhered well. The conductor band has only a very small height in the direction of a thickness of a future card, which height has a positive impact on a card design.

The circuit layout is suitable in particular for the production of a security documents such as, for example, smart cards, credit cards, electronic identity cards or electronic health cards and can be produced in a simple, cost-effective and highly productive manner. The circuit layout according to the invention has a very small thickness of less than 0.4 mm, has low mechanical stresses, can be further processed by means of adhesion or lamination and thus renders possible a high design quality of a final laminate. In particular due to a complete embedding of the conductor strip into the substrate, a conductor strip surface and a substrate surface have virtually the same level. Thus better adhesion results or lamination results are produced with subsequent processing steps. Complex circuits in security cards, smart cards and the like or comparable applications can be produced using different materials, for example, polycarbonate (PC) or other thermoplastics or synthetic papers, woven fabrics (very dense or very thin and level), metals or wood as substrate.

The following advantages are achieved by a laying and embedding of conductor strip: Flat, wide and level contacting regions are available for the contacting of the electronic components. The conductor strips have a much smaller thickness than wire of the same cross section, and they can be attached well to the substrate or embedded well into the substrate. Conductor strips can be contacted and adhered well. The conductor strips in the direction of the thickness of the future card have only a very small height, which has a positive effect on a card design. The conductor strips themselves can bear security features.

Due to the larger surface of the conductor strip in relation to the conductor wire of the same cross section, conductor strip is very suitable for applications in the ultrahigh frequency range since, due to a skin effect, an electrical resistance of wire conductors is substantial in ranges of very high frequency. Furthermore, through the wide conductor strips, an active surface of the semiconductor chip contacted on the conductor strips is optically very greatly shaded.

Electronic components that can be arranged on the substrate are, for example, semiconductor chips, the connections of which can be contact bumps and/or fine wires, modules (semiconductor chip on a chip carrier with enlarged contacts and plastic covering to protect the chip and the microcontacting), resistors, capacitors, diodes, short-circuit pieces, switches and the like. The semiconductor chips advantageously have contact bumps as contact points, wherein depending on the contacting method the contact bumps can be of gold, of nickel, of copper with nickel coating, of copper or nickel with solder coating, of palladium, hardened conductor adhesive or other materials. The circuit pattern is composed of at least one conductor strip drawing, which has any desired number of circular-arc shaped changes in direction according to the circuit to be realized. The contacting region is only that proportional area, electrically insulated or stripped of insulation, of the conductor strip on which a contact connection with a contact of the electronic component or with a further conductor strip drawing will take place. Other areas of the conductor strip are insulated in order to avoid possible short-circuits with chip edges or the like.

Conductor strip can be arranged on only one surface side or also on both surface sides of the substrate and/or can be embedded in the respective surface side. One or more circuit arrangements can thereby be produced on the substrate, which are contacted with one another or are independent of one another.

In an advantageous embodiment, the electronic component is arranged on a surface side of the substrate. Preferably, the substrate has at least one through hole. In a further embodiment the electronic component is arranged in this through hole. Expediently, at least the one conductor strip spans the through hole so that the component is contacted with the conductor strip or with several conductor strips spanning the through hole. In a further preferred embodiment, conductor strips are arranged on both surface sides of the substrate and span the through hole in the substrate, wherein contacting regions of the conductor strips are electrically connected to one another through the through hole. The conductor strips are welded to one another through the through hole, for example, and contacted to one another in this manner.

In another advantageous embodiment, the conductor strips are electrically connected to one another via a metal piece arranged in the through hole. If an electronic component is arranged in the through hole, this can be electrically contacted to circuit patterns on both sides of the substrate.

Furthermore, the conductor strips can also be arranged on both surface sides of the substrate without being electrically connected to one another through the through hole. They can thereby also merely span a through hole and not be electrically contacted to one another thereby. Circuit patterns can be produced on both sides of the substrate through the conductor strips on both surface sides, which conductor strips can be electrically contacted to one another or not.

Expediently, the substrate is of a thermoplastic material so that it can be melted at least in part by means of a thermal or ultrasonic vibration-assisted method, for example, and the conductor strip can be embedded in the substrate.

Expediently, the conductor strip is of copper or of a copper alloy and preferably has a high ductility. Copper and copper alloys ensure a high electric conductivity, a high ductility and good soldering and welding properties. Through the high ductility, the conductor strip can be easily deformed and thus can easily be laid on the substrate.

Preferably, the conductor strip has a surface layer up to 3 μm thick of a precious metal, in particular of silver. An improved contact quality with the electronic components can be achieved thereby.

In an advantageous embodiment, the conductor strip has a pattern-like embossing at least on one surface side at least over a part of its length. This embossing on the one hand can improve a connection of conductor strip and substrate or an electric contacting of the component, and on the other hand can serve as a security feature.

Preferably, the conductor strip is coated with a meltable insulating varnish at least on a surface side facing towards the substrate, which insulating varnish expediently comprises a core varnish layer that is heat resistant up to temperatures of 190° to 350° C. and a baked varnish layer that is meltable at temperatures from 130° C. During a laying of the conductor strip on the substrate, the baked varnish layer is meltable and thus the conductor strip can be bonded firmly onto the substrate. If the conductor strip attached in or on the substrate has metallic surfaces on a face side, it is advantageous if the conductor strip has insulating varnish only on the surface side facing towards the substrate. A coating of only one surface side of the conductor strip with insulating varnish can also be advantageous for reasons of reducing thickness or improving design quality. Expediently, a first cover film, preferably of a thermoplastic material, is arranged on at least one surface side of the substrate. This first cover film advantageously spans at least the through hole in the substrate and is connected by lamination and/or adhesion to the substrate at least in a surrounding region of the through hole. The first cover film can be connected to the substrate, for example, by a very short lamination process by means of pressure and heat or pressure and ultrasonic energy. The electronic component is thus covered and protected. The cover film can likewise be composed, for example, of paper, paper-like materials or woven fabric.

It is furthermore advantageous if likewise the first cover film, preferably a thermoplastic cover film, is attached to the second surface side of the substrate film at least in the area of the through hole and the surrounding area and is connected to the substrate film by lamination by means of pressure and heat, so that the electronic component and the circuit are optimally protected. A cavity is formed by the cover films around the component in the through hole, which cavity is filled by means of potting material or adhesive, whereby the component is securely held and protected. At least one conductor strip section with a contacting point stripped of insulation in a defined manner with respect to the further circuit is firmly connected to a base of the cavity and located in a defined flat position. A very strong optical shading of the active surface of the contacted semiconductor chip results due to the wide conductor strips.

In an advantageous embodiment, a second cover film is arranged between the first cover film and the substrate, which second cover film expediently is of a thermoplastic material. The second cover film expediently has at least one recess for embedding the electronic component. The first cover film expediently spans at least the recess in the second cover film. The second cover film is preferably connected to the substrate and/or to the first cover film by lamination and/or adhesion. The component can thereby be arranged on the substrate and is surrounded by the second cover film. It is covered by the first cover film and thus protected. The recess is firmly closed by the first cover film, whereby a defined cavity for accommodating the electronic component is formed. At least one conductor strip section with a contacting point stripped of insulation in a defined manner with respect to the further circuit is located in a defined flat position and firmly connected to the base of the cavity. A very strong optical shading of the active surface of the contacted semiconductor chip results due to the wide conductor strips.

Preferably, the electronic component for insulating and/or attachment on the substrate, is surrounded at least in some regions by a potting material and/or by an adhesive at least one conductor strip and/or on at least one cover film. This results in the following advantages: the component is placed by means of one of the usual cost-effective flip chip contacting methods on the flat and metallic conductor strip sections produced in a very cost-effective manner, for example, in the cavity and the residual volume of the cavity is filled with adhesive capable of being cured. The component is protected from edge shorting with other areas of the conductor strips by the insulating varnish still present on the conductor strip sections outside the contacting regions and through subsequently introduced potting material. The component and the contacting are located completely in the cavity. The component is centrally located in the through hole of the substrate film. This position protects the component against asymmetrical mechanical stresses that might otherwise possibly occur.

The circuit layout renders possible a layer-symmetrical prelaminate with electronic components inserted into one or more cavities, contacted and embedded in potting materials or adhesive. If, as components, semiconductor chips are flip chip contacted by means of adhesion, the otherwise usual curing of the adhesive by means of thermodes individually placed on the chips can be omitted so that the chips projecting slightly beyond the cavity can be pressed via the placed cover film during lamination in the direction of conductor strip sections and in this position can be fixed by the curing adhesive or the potting material. Contacting and lamination are possible in one step with lowest possible thermal stress of the substrate film and avoiding shear effects of the substrate films and cover films on the electronic components and their contacting with the conductor strips. Thermode arrangements that are expensive in terms of cost and adjustment can thus be avoided.

The circuit layout according to the invention and the embodiments thereof render possible the production of contactless chip cards, complex chip cards and simple electric circuits using the wide conductor strip. Very level, flat and very reliable circuits can thereby be produced, which are similar to thin printed circuit boards provided on one or both sides with conductor paths, but have the advantage compared thereto of a very flexible production, electrically insulated conductor crossings that are easy to produce and a spanning of through holes. This is not possible with printed circuit boards, or is possible only with a very high expenditure. Furthermore, defined cavities with conductor strips attached to the cavity base can be produced. The cavities or through holes in the substrate can thus be spanned very easily with the wide conductor strip.

The wide conductor strip furthermore renders possible very wide contacting surfaces, which render possible a secure flip chip contacting and facilitate laser contacting or thermal compression contacting, since level and thin metal surfaces simplify the energy input and energy conduction and allow them to be more precisely controlled than the round wires or twisted rectangular wires used in the prior art. Furthermore, due to the wide conductor strips, an active surface of the semiconductor chip contacted on the conductor strips is optically very strongly shaded.

In a method to produce a circuit pattern on a substrate, according to the invention at least one conductor strip is attached in a twist-free manner on at least one surface side of the substrate, which conductor strip is coated with a meltable insulating varnish on at least one surface side facing towards the substrate, wherein the insulating varnish is heated by thermal energy or by means of ultrasound and at least partially melted and the conductor strip is pressed onto the substrate in a twist-free manner. The ultrasonic frequency can be 40 kHz to 140 kHz.

The term conductor strip means a strip-shaped electric conductor, the width of which is at least four times its thickness.

Preferably, the width of the conductor strip is ten times to one hundred times its thickness.

Advantageously, the conductor strip has a thickness of at least 5 μm.

Preferably, the conductor strip has a width of 0.2 mm to 1 mm, particularly preferably 0.25 mm to 1 mm and a thickness of 10 μm to 50 μm.

The conductor strip is attached to the substrate in a straight or circular arc-shaped manner in predetermined radii and free from kinks.

The conductor strip with comparable capacity thus has a much smaller thickness than wire of the same cross section and can be attached to the substrate well or can be embedded well into the substrate. The conductor strip can be contacted and adhered well. The conductor strip has only a very small height in the direction of a thickness of a future card, which has a positive impact on a card design.

Through the brief melting due to an energy supply through ultrasonic vibrations or through the supply of thermal energy through laser light or heating by a heated laying tool or by partially dissolving a baked varnish layer of the insulating varnish by a suitable solvent, the baked varnish layer is temporarily softened so that it forms an adhesive connection to the substrate surface lying beneath in order to subsequently return to the solid state again by cooling or by evaporating the solvent. A circuit pattern is thereby produced on the substrate and the conductor strip is optimally attached to the substrate.

The following advantages result due to a laying and embedding of the conductor strip: flat, wide and level contacting areas are available for the contacting of electronic components. The conductor strips have a much smaller thickness than wire of the same cross section and they can be attached well to the substrate or can be embedded well into the substrate. Conductor strips can be contacted and adhered well. The conductor strips have only a very small height in the direction of the thickness of the future card, which has a positive impact on a card design. The conductor strips themselves can bear security features.

Due to the larger surface of the conductor strip in relation to the conductor wire of the same cross section, a conductor strip is very suitable for applications in the ultra high frequency range, since an electrical resistance of wire conductors is considerable in areas of very high frequency due to a skin effect. Furthermore, through the wide conductor strips an active surface of the semiconductor chip contacted to the conductor strips is optically very greatly shaded.

Electronic components that can be arranged on the substrate are, for example, semiconductor chips, the contacts of which can be contact bumps and/or fine wires, modules (semiconductor chip on a chip carrier with enlarged contacts and plastic covering to protect the chip and the microcontacting), resistors, capacitors, diodes, short-circuit pieces, switches and the like. Advantageously, the semiconductor chips have contact bumps as contact points, wherein depending on the contacting method the contact bumps can be of gold, of nickel, of gold with nickel coating, of copper or nickel with solder coating, of palladium, of cured conductive adhesive or other materials. The circuit pattern is composed of at least one conductor strip drawing, which has any desired number of circular arc-shaped changes in direction according to the circuit to be realized. The contacting region is only that proportional area of the conductor strip electrically insulated or stripped of insulation, on which a contact connection with a contact of the electronic component or with a further conductor strip drawing is carried out. Other areas of the conductor strip are insulated in order to avoid possible short circuits with chip edges or the like.

In an advantageous embodiment, before the application of the conductor strip, the substrate is pre-heated at least in one region of the circuit pattern to be produced. This is particularly advantageous with thermoplastic substrates with high softening or melting points (e.g., polycarbonate) and with substrates of metals or similar materials. A necessary energy input, which is to be produced by a laying tool, is thereby reduced and a laying productivity is increased.

In an advantageous embodiment, a surface of the substrate is heated by thermal energy or by means of ultrasound and at least partially melted and the conductor strip is pressed at least partly into the substrate with displacement and/or compression of a material of the substrate. The conductor strip surface and the substrate surface thereby have virtually the same level, whereby better adhesion or lamination results are achieved with subsequent processing steps. Advantageously, the laying of the conductor strip in an ultrasonic vibration assisted manner is to be used as a laying method. Thermally assisted laying methods require conductor strips that are not insulated at least on one side for a defect-free laying. The laying of conductor strips by adhesion of the partially dissolved insulation varnish is not productive and solvent emissions occur.

Expediently, the conductor strip is laid by means of a laying tool, wherein the laying tool is moved relative to the substrate and/or the substrate is moved relative to the laying tool. The laying tool performs relative movements in the substrate plane on the substrate, which movements exactly represent the circuit pattern to be produced. The relative movement can be carried out by movement of the laying tool on the substrate, by moving the substrate under the placed laying tool or by moving the laying tool and the substrate. The movement of the laying tool and/or the substrate in order to produce the relative movement can be carried out in particular in the x direction and/or in the y direction of a three-dimensional coordinate system. A movement in the z direction can be carried out, for example, to place the laying tool on the substrate. The x direction and the y direction of the three-dimensional coordinate system span a horizontal plane, the x direction and the y direction with the z direction of the three-dimensional coordinate system respectively span one vertical plan.

A rotation of the substrate and/or of the laying tool about an axis of rotation perpendicular to the substrate surface is possible, wherein the rotation of the laying tool is also advantageous. The rotation of the substrate, however, is not very useful in particular with a plurality of laying tools arranged in a parallel manner, which produce circuit patterns on the substrate in a parallel manner, whereby an increase in productivity can be achieved.

The conductor strip is preferably unwound from a conductor strip coil, which is coupled to a drive unit so that the unwinding is carried out without jolting and with a low action of force on the conductor strip. The conductor strip coil is constantly pivoted with it during the laying of the conductor strip so that the conductor strip is not twisted.

In an advantageous embodiment, a pattern-like embossing is embossed on at least one surface side of the conductor strip by means of an embossing device. Through the embossing device conductor strip that does not have a necessary width in the assembly area of the electronic components can be deformed by means of an embossing operation before the laying such that a necessary increased strip width of the conductor strip in a region and surrounding region of the component to be contacted is produced. Likewise it can be advantageous for some applications to use conductor wire for laying the circuit pattern and to produce the necessary width of the conductor strip section in an assembly region of the component and in its surrounding region by embossing. Furthermore, a relief-like surface can be formed in the conductor strip by embossing before the embedding into the substrate. That is, for example, security features or product identifiers can be pressed in or microroughnesses can be produced to improve the contacting in the contacting region.

Expediently, contacting regions of the conductor strip are stripped of insulation after the laying of the conductor strip. The insulating varnish is preferably removed by means of laser radiation, evaporated and/or burnt. If the contacting regions are facing towards the laser beam, the stripping of insulation is carried out by direct burning of the insulating varnish by means of very long-wave infrared laser light, for example, through an energy beam of a CO2 laser. If the contacting region lies on the side of the conductor strip section facing away from the laser beam, a laser beam with a wave length in the near infrared range, for example at 900 nm is to be used; this heats a conductor material of the contacting region so that the insulating varnish on both sides of the conductor strip is evaporated or burnt. This results in the following advantages:

The conductor strip sections produce for subsequent contacting large and level surfaces, which on the one hand still have a varnish insulator and on the other hand have contacting regions of defined position stripped of insulation. The stripping of insulation by means of laser after laying can compensate for any incorrect positions of the conductor strips and/or the through holes in that after image location detection according to predetermined picture marks, circuit patterns or through holes, the contacting points stripped of insulation are produced in the predetermined region and an insulated region of the conductor strip section in a provided assembly region of the electronic component thus does not have to be reduced unnecessarily.

In an advantageous embodiment, the conductor strip or a plurality of conductor strips are applied on a surface side of the substrate crossing themselves and/or crossing one another. Several different circuit patterns can thereby be arranged on one side of the substrate. At one connection point, respectively one conductor strip section of the circuit pattern thereby lies crossed one on top of the other and both conductor strip sections are contacted with one another. The conductor strips are preferably stripped of insulation and welded to one another by a compressing and a simultaneous pulse-like heating above 900° C. for a duration of up to 100 ms. In another embodiment, contacting areas of the conductor strips are stripped of insulation, a solder material or a conductive adhesive is applied to these contacting areas and the conductor strips are electrically connected to one another with melting of the solder material or with curing of the conductive adhesive. Furthermore, the conductor strip or a plurality of conductor strips can also be applied to both surface sides of the substrate in the described manner respectively crossing themselves and/or crossing one another.

It is advantageous thereby if a lower conductor strip section has a contacting area stripped of insulation that is large in area with respect to the conductor crossing and the stripping of insulation is carried out before the laying of the second crossing circuit pattern. The contacting itself can be realized with different methods.

The most cost-effective method is the contacting by means of pulse-like thermal compression welding in which a thermode is placed on the crossing area, the conductor strip sections are pressed against the substrate and at the same time the thermode is heated within less than equal to 0.1 seconds to temperatures greater than equal to 900° C.

In an alternative method, before the laying of the second circuit pattern on the contacting area solder material is deposited, thereafter the second circuit pattern is laid and subsequently the insulation lying on the solder material is at least partially destroyed and the solder material is melted by means of punctiform, brief and extreme heating of the deposited second conductor strip section so that the solder material connects the conductor strip sections crossing one another.

In a further alternative method, after the laying of the conductor strip sections crossing one another, contacting areas lying next to one another are created by stripping the insulation of both conductor strip sections, wherein the edge of the upper crossing conductor strip section is at least partially stripped of insulation, thereafter the solder material is applied and the contacting of the crossing conductor strip sections is realized through punctiform and brief heating of the solder material. Further alternative contacting methods are the use of electrically conductive adhesive in place of solder material or the mechanical connection of the conductor strip sections crossing one another by means of micro-clinches. The following advantages result: with the given solution more complex circuits are possible on one substrate side, also with different conductor strips. Secure and very flat connection points can be produced.

In a further advantageous embodiment, conductor strips are attached on both surface sides of the substrate and electrically connected to one another through a through hole in the substrate. In a first connection method the contacting is carried out by pressing together both conductor strips sections in the through hole and through subsequent thermal compression welding. In an alternative connection method, after the laying of the first conductor strip section into the through hole a metallic conductor piece of the size of the through hole minus the thickness of the conductor strip sections on both sides is inserted, thereafter on the other substrate side the circuit is laid and subsequently the through-hole plating is carried out through thermal compression welding twice on both sides.

Furthermore, the conductor strips can be arranged on both surface sides of the substrate without being electrically connected to one another through the through hole. They can also thereby only span a through hole and not be electrically connected thereby to one another. Circuit patterns can be produced on both sides of the substrate through the conductor strips on both surface sides, which can be electrically contacted to one another or not.

In a second alternative connection method, after the laying of a very wide conductor strip section that completely closes the through hole on one side, and the production of the intended contacting area stripped of insulation on the substrate side of the conductor strip section, a narrow conductor strip section only partially closing the through hole is laid and briefly heated by laser energy input such that the insulating varnish on the through hole side is evaporated or burnt and thereafter the cavity is filled with solder paste and subsequently the solder paste is melted.

In a third alternative connection method, after the laying of a very wide conductor strip section that completely closes the through hole on one side, and the production of the intended contacting area stripped of insulation on the substrate side of the conductor strip section, a narrow conductor strip section only partially closing the through hole is laid and briefly heated by laser energy input such that the insulating varnish on the through hole side evaporates or burns, the cavity is filled with electrically conductive pasty filler. The curing of the filler finally is carried out after placement of cover films on the substrate during the laminating operation.

The advantage results that with little expenditure one or more circuits can be electrically connected to one another on both sides of the substrate and that the connecting point is securely embedded into the substrate or into the prelaminate.

A supplementary embodiment of the solution according to the invention results for a substrate with at least one circuit pattern embedded in or on each substrate side, wherein at least one electronic or electric component is located in at least one through hole of the substrate film and the contact points of the component pointing to both sides of the substrate film are connected to contacting areas of the conductor strip sections of the circuit pattern on both sides of the substrate film.

After the laying of the circuit pattern in or on a substrate side, the element is placed in the cavity, subsequently the circuit pattern is laid in or on the second substrate side and finally the contacting is carried out through pulse-like thermal compression welding from both substrate sides.

With another approach, after laying of the circuit pattern in or on a substrate side, the contacting areas of the conductor strip sections are created by stripping insulation, and solder material (for example, solder paste) is deposited onto the contacting areas, thereafter the electronic component is placed in the cavity and likewise solder material is applied onto the contact points thereof, subsequently the circuit pattern is laid in or on the second substrate side, thereafter the contacting areas are stripped of insulation by punctiform extreme heating of the conductor strip section, and thereby the contacting of these component connections is carried out at the same time. In a next step the contacting areas of the conductor strip sections of the first substrate side are connected to the component connections through solder contacting by means of punctiform heating.

In a further approach, after the laying of the circuit pattern in or on a substrate side, the contacting areas of the conductor strip sections are produced by stripping insulation, thereafter conductive paste is applied onto the contacting areas, the electronic component is placed in the cavity, likewise conductive paste is applied onto the contact points thereof and in a further step at least one circuit pattern is laid into the second substrate side, the contacting areas are stripped of insulation by punctiform extreme heating of the conductor strip sections, finally cover films are placed on both substrate sides and connected to the substrate by lamination with curing of the conductive adhesive.

The following advantages result: electronic or electric components with spatially distributed contacts can be mounted and contacted in the substrate; e.g., batteries, light-emitting diodes, piezoelectric elements, etc. Known methods of contacting can be used thereby. Pre-soldered electronic component contacts or electronic component contacts coated with thermoplastic conductive adhesive can also be used advantageously. The cavities can be filled with casting resins; the electric conductive adhesive contacting, the soldering (at least with low-melting solders) and the curing of the cavity-filling resins can be carried out during the lamination.

In a further advantageous embodiment of the invention, after the laying of the circuit pattern into a substrate side the contacting areas of the conductor strip sections are stripped of insulation, thereafter the electronic component is placed on the substrate surface and the component contacts are connected to the contacting areas.

In a first solution, the component is attached by its rear side to the substrate preferably by adhesion, subsequently the contact points of the component are connected to the contacting areas by fine-wire bonding or ribbon bonding and finally the component, contacting areas and the fine wire or the contacting ribbons are protected by means of curable potting material.

In a further solution, the component is connected to the contacting areas of the conductor strip sections by means of flip chip contacting. The protection of the component and the contacting areas is carried out by adhesion and potting material.

In a third solution, the component is adhered to the substrate film, and the contacting is carried out by the application and melting of solder material or by the application and curing of electrically conductive adhesive. An extension of this embodiment of the solution according to the invention results in that before or after the contacting, a cover film with a through hole in the size of the area of the component and its contacting and the thickness of the component including its contacting is applied to the substrate film and at least in the surrounding area of the through hole is connected thereto by lamination such that the component after the contacting lies protected in the cavity created by the cover film. The residual volume of the cavity is filled by adhesive or potting material. This embodiment of the solution according to the invention makes it possible to use substrates with circuit patterns of conductor strip analogously to a printed circuit board without the disadvantages of a cost-intensive, etch-structured printed circuit board that cannot be laminated with further thermoplastic layers and without the disadvantages of a substrate printed with cost-intensive conductive pastes and thermally pretreated multiple times and shrunk.

With an advantageous embodiment of the method a through hole in the substrate is closed on one side by means of a first cover film on a surface side of the substrate on which the circuit pattern is arranged, adhesive or potting material is measured into a cavity formed thereby, the electronic component is placed into the cavity and pressed with contacts against contacting regions of the conductor strip. A further first cover film is placed on a surface side of the substrate without circuit pattern and in a joint process step the two first cover films and the substrate with circuit pattern inserted thereon or therein and electronic component placed therein are laminated with compression, wherein the contacts of the electronic component are pressed against the contacting regions and contacted and the adhesive or the potting material is cured at laminating temperature. This results in a highly productive production with a very low number of process steps.

The method according to the invention and the embodiments thereof render possible the production of contactless chip cards, complex chip cards and simple electric circuits using this wide circuit strip. Very level, flat and very reliable circuits can be produced thereby, which are similar to thin printed circuit boards provided with conductor paths on one or both sides, but compared thereto have the advantages of a very flexible production, electrically insulated conductor crossings that are easy to produce and a spanning of through holes. This is not possible with printed circuit boards or is possible only with a very high expenditure. Furthermore, defined cavities with conductor strips attached to the cavity base can be created and a chip contacting in these cavities is simplified by combining the steps curing of the chip-contacting adhesive, filling the residual cavity with adhesive and lamination. The cavities or through holes in the substrate can be spanned very simply with a wide conductor strip.

Very cost-effective circuit layouts can be produced with high productivity, a reduced number of work steps and with low expenditure in terms of energy and equipment in the form of the above-referenced products, which have a high optical quality, a high precision of the conductor path pattern, a low tolerance of electrical characteristic values and a high reliability. In particular, substrates without an additional adhesive coating can be used to produce the circuit layout.

The wide conductor strip furthermore renders possible very wide contacting areas which render possible a secure flip chip contacting and facilitate laser contacting or thermal compression contacting, since level and thin metal areas simplify the energy input and the energy conduction and allow them to be controlled more precisely than the round wires or twisted rectangular wires used in the prior art. Furthermore, an active surface of the semiconductor chip contacted to the conductor strips is optically very strongly shaded through the wide conductor strips.

A device for producing a circuit pattern on a substrate comprises a conductor strip coil and a cylindrical or conical laying tool, which at least over a part of its length has an interior bore guiding the conductor strip and an annular active area arranged perpendicular to its longitudinal axis and merging in inner and outer radius.

According to the invention, the conductor strip coil is arranged in a pivoted manner about a horizontal axis of rotation in a coil receptacle, which is pivoted about a vertical axis of rotation, wherein the coil receptacle can be turned by means of a tracker device in the case of changes in direction during a laying of the conductor strip on the substrate such that the conductor strip can be unwound in a twist-free manner tangentially from the conductor strip coil.

By means of the device the conductor strip can be arranged on and/or in the substrate in a straight or circular arc-shaped manner in predetermined radii and free from kinks.

The laying tool is excited by ultrasonic energy, for example, so that the insulating varnish of the conductor strip is meltable. With the use of a suitable substrate, this is also optionally meltable at least in part. The conductor strip can be unwound tangentially from a coil body. The axis of the cylindrical or conical conductor strip coil lies in or almost in a parallel plane to the substrate surface.

It is expedient to pivot the axis of the conductor strip coil in the axis parallel to the substrate plane and during the laying of circuit patterns with changes of direction of the conductor strip on the substrate to track the conductor strip coil around the axis perpendicular to the substrate plane such that the conductor strip is always fed free from twists to the active area of the laying tool. If the conductor strip is to be fed via deflection devices to the active area of the laying tool, the conductor strip coil and the deflection devices connected directly or indirectly thereto are to be tracked in the same direction of rotation and at the same angle by rotation according to the changes in direction and angle of the circuit pattern to be laid such that the conductor strip can be laid in a twist-free manner on the substrate and optionally the laying tool is likewise to be tracked according to the changes in direction and angle of the circuit pattern to be laid through the rotation of its axis standing perpendicular to the substrate plane. This ensures that the conductor strip can be fed to the laying tool in a twist-free manner. This is absolutely essential in particular with one-sided changes in direction as in the laying of coil patterns and concentric antennas.

The laying tool is cylindrical pin-shaped or embodied in a conical manner, and it has at least over a part of its length an interior bore and an annular active area merging into inner and outer radius and arranged parallel to the substrate surface to be processed.

The laying tool performs relative movements on the substrate in the substrate plane, which relative movements represent exactly the circuit pattern to be produced. The relative movement can be carried out by moving the laying tool on the substrate, by moving the substrate under the placed laying tool or by moving the laying tool and the substrate.

The movement of the laying tool and/or the substrate in order to produce the relative movement can be carried out in particular in the x direction and/or in the y direction of a three-dimensional coordinate system. A movement in the z direction can be carried out, for example, to place the laying tool on the substrate. The x direction and the y direction of the three-dimensional coordinate system span a horizontal plane, the x direction and the y direction together with the z direction of the three-dimensional coordinate system respectively span a vertical plane.

A rotation of the substrate and/or of the laying tool about an axis of rotation perpendicular to the substrate surface is possible, wherein the rotation of the laying tool is also advantageous. However, the rotation of the substrate is not very useful, in particular with a plurality of laying tools arranged in a parallel manner, which produce circuit patterns on the substrate in a parallel manner, whereby an increase in productivity can be achieved.

In a preferred embodiment an embossing device is arranged between the conductor strip coil and the laying tool, which embossing device expediently comprises a fixed anvil and a moveable anvil, wherein embossed surfaces of the anvils are aligned parallel to surface sides of the conductor strip guided through between the anvils. Particularly preferably an embossed pattern is inserted at least in the embossing surface of one anvil.

Conductor strip sections with a deformation width greater than the strip width of the conductor strip unwound from the conductor coil can thus be produced by defined embossing of conductor strip pieces through the embossing device with two anvils of a defined embossing length acting against one another, wherein the anvil surfaces are arranged vertically or almost vertically and the conductor strip to be embossed is guided with parallel surfaces between the anvils. According to the length of the conductor strip between the embossing device and the active area of the laying tool under low tensile stress, the embossing operation is to be started at the point during the laying of the circuit pattern from which until the surrounding area of the component to be mounted is reached this length of conductor strip still has to be laid. During the embossing of deformation widths, the length of the conductor strip section to be embossed is the length of the surrounding area of the component to be mounted.

To avoid twisting the conductor strip during the laying, this embossing device is rotatable in the same direction and at the same angle with the conductor strip coil around the vertical axis. It is expedient to mechanically connect the unwinding device and the embossing device. A further improvement results when the embossing anvils can be acted on with different and defined pressing forces, when the anvil surfaces can be cooled and when two or more embossing devices are arranged in the conductor strip sequence.

Defined-width conductor strip sections and section widths, which are wider than the conductor strip otherwise laid for the circuit pattern, result due to the embossing with defined contact geometries. Through the selection of the pressing forces, as needed different deformation widths can be produced. The cooling and the moistening of the anvil surfaces associated therewith prevent the insulating varnishes from baking on the contact surfaces. With certain types of contacting, for example, flip chip contacting, the reliability of the contact is increased by an embossed relief If conductor wire is used to produce the circuit pattern, large deformation widths can likewise be achieved by means of embossing.

Preferably, a conductor strip guide device is arranged between the embossing device and the laying tool, which expediently is connected to the coil receptacle and to the embossing device. Particularly preferably, the conductor strip guide device comprises two fixedly installed deflection rollers arranged vertically one under the other and a spring-mounted deflection roller arranged between them and moveable horizontally. This spring-mounted deflection roller can be deflected to a maximum by a spring force perpendicular to a virtual vertical axis of the two fixedly mounted deflection rollers, i.e., it can be deflected out of this virtual axis, wherein this virtual vertical axis also runs through rotation points of the two fixedly mounted deflection rollers.

The conductor strip or the conductor wire winds around the moveably supported deflection roller on the other side than on the fixedly mounted deflection rollers. The moveable deflection roller is resiliently deflected to the maximum out of the connecting line of the two fixedly mounted deflection rollers during the laying of the circuit pattern and the conductor wire or the conductor strip forms a storage loop. The spring force is measured such that the deflection is reduced during a tensile force action on the conductor wire or the conductor strip. The spring mounted deflection roll is deflected to a maximum during the laying of a circuit pattern.

During the embossing, a feed stoppage of the conductor wire or of the conductor strip from the conductor wire coil or the conductor strip coil occurs, which causes an immediate increase of the tensile force on the conductor wire or the conductor strip. The deflection of the spring-mounted deflection roller is reduced thereby, so that the conductor wire or the conductor strip can be freely released from the storage loop. An uninterrupted laying operation is thereby also rendered possible during the embossing. This results in the following advantage: The embossing of the strip-like conductor pieces is also possible in principle during a stoppage of the laying, but with the use of the conductor strip guide device a higher laying productivity can be achieved, since no laying stoppage is necessary during the embossing. The given conductor strip guide device represents only the principle of a conductor strip storage; the conductor strip tension can also be monitored via sensors and the moveable roller can be held or moved via special drives. With conductor strips that already have the necessary width in the assembly area of the electronic components, the embossing and guide devices are not necessary.

In a further preferred embodiment, the conductor strip coil is coupled with a drive unit. This can be realized, for example, by means of a motor with a power transmission to the conductor strip coil, for example by means of drive rollers, driven rollers and/or by means of at least one drive belt.

Furthermore, the device preferably has a vertically moveable deflection roller with damping weight. In this manner, a conductor strip reserve loop can be unrolled from the conductor strip coil so that a uniform laying of the conductor strip free from jolts is ensured. a uniform unreeling of the conductor strip and a high laying speed are ensured with low tensile force on the conductor strip by the drive unit and furthermore by the vertically moveable deflection roller with damping weight.

To monitor the conductor strip reserve loop, the device has, for example, at least one sensor. The drive unit can thus always be controlled and/or regulated such that sufficient conductor strip for laying is always available, i.e., a sufficient conductor strip reserve loop is also always available. The conductor strip unwinding from the conductor strip coil can be carried out largely continuously due to the conductor strip reserve loop, so that the conductor strip coil does not always need to be rolled and stopped again.

The laying tool can likewise be attached to the coil holder and rotate with it, however, a separate suspension of the laying tool is to be preferred, since this renders possible better dynamics of the laying tool in particular with movements perpendicular to the substrate surface, renders possible a better force control and renders possible a more uniform wear of the active area of the laying tool. The important factor is that the conductor strip falls free of kinks and without guidance via deflection edges from the deflection coil into the laying tool. As soon as a conductor strip pattern has been laid and the tool is to adopt a different position while being lifted from the substrate surface, a strip clamp has to be closed before hand in order to prevent a retraction of the conductor strip through the deflection roller or a change in the conductor strip position in the laying tool. Before the start of laying, the strip clamp must be opened again. Through the described approach a feed of the conductor strip to the laying tool is carried out in a twist-free manner, a predetermined and low conductor strip prestressing is obtained and the conductor strip is essentially continuously unwound from the conductor strip coil even at laying speeds in the range of 10 cm/s to 100 cm/s and marked changes in speed (narrow radii, meandering patterns). This prevents the conductor strip during unwinding from stretching longitudinally and thus changes its geometry, its strength and its electrical characteristic values. To guarantee the conductor strip reserve loop, further technical options can also be used, for example, by means of airflow.

The device according to the invention and the embodiments thereof render possible a continuous straight and in particular curved and coil-shaped, completely level, twist-free, crease-free, crack-free and wrinkle-free flat laying and adhesion of a wide conductor strip in any, even concentric, patterns on a substrate.

Circuit layouts with small radii can be produced with the device with a co-pivoting conductor strip coil, i.e., the radii are larger than approximately four times the width of the conductor strip. All useful circuit patterns can thus be produced with the conductor strip and the radii achievable therewith.

In all of the embodiments the device expediently has a separating device, by means of which the conductor strip can be severed so that conductor strip laid on the substrate can be separated from conductor strip that has not yet been laid, which is still in the device, for example, after the circuit pattern has been produced in full on the substrate and the laying of the conductor strip has been completed.

The conductor strip should be wound on the coil parallel next to one another and free from twists layer upon layer in order to avoid any preliminary damage (kinks, warping, tangles of the conductor strip on the conductor strip coil, and to ensure easy unwinding.

The term conductor strip means a strip-shaped electric conductor, the width of which is at least four times its thickness.

Preferably, the width of the conductor strip is ten times to one hundred times its thickness.

Advantageously, the conductor strip has a thickness of at least 5 μm.

Preferably, the conductor strip has a width of 0.2 mm to 1 mm, particularly preferably 0.25 mm to 1 mm, and a thickness of 10 μm to 50 μm.

Exemplary embodiments of the invention are described in more detail below based on drawings.

They show:

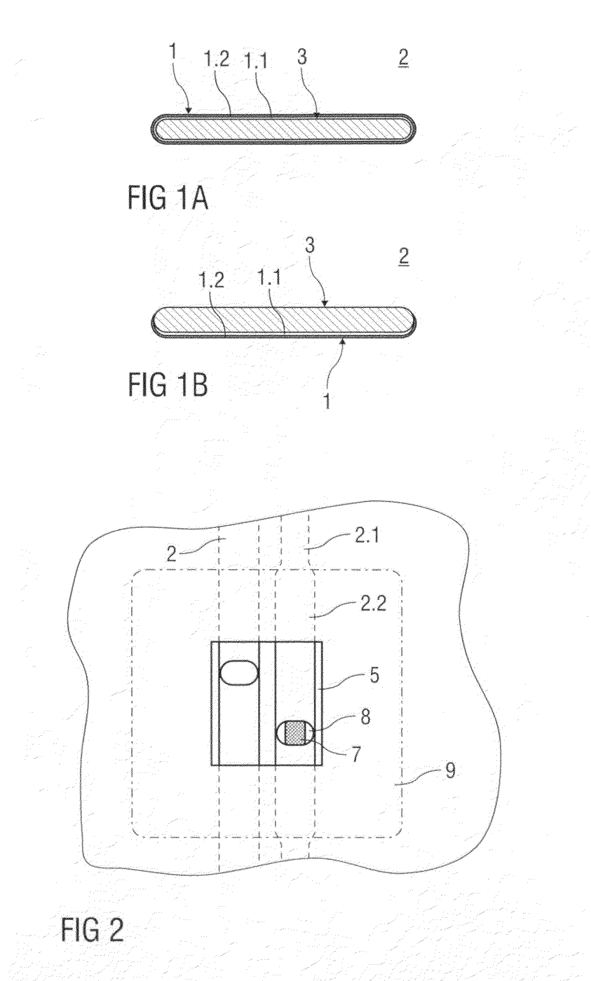

FIG. 1a A first embodiment of varnish-insulated conductor strip in cross section,

FIG. 1b A second embodiment of varnish-insulated conductor strip in cross section,

FIG. 2 A section from a substrate with a through hole and laid conductor strips in plan view,

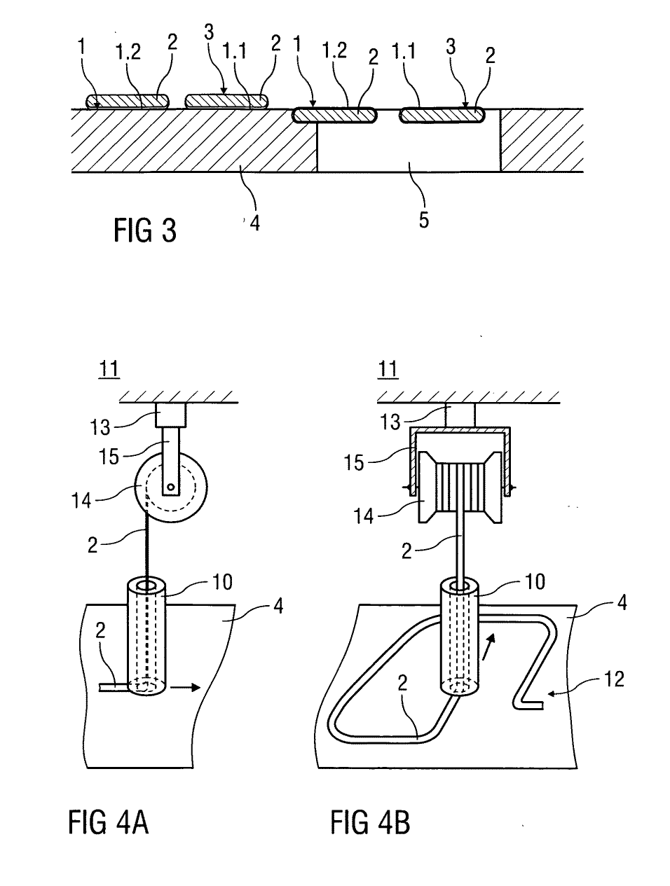

FIG. 3 A cross section through a substrate with laid conductor strips,

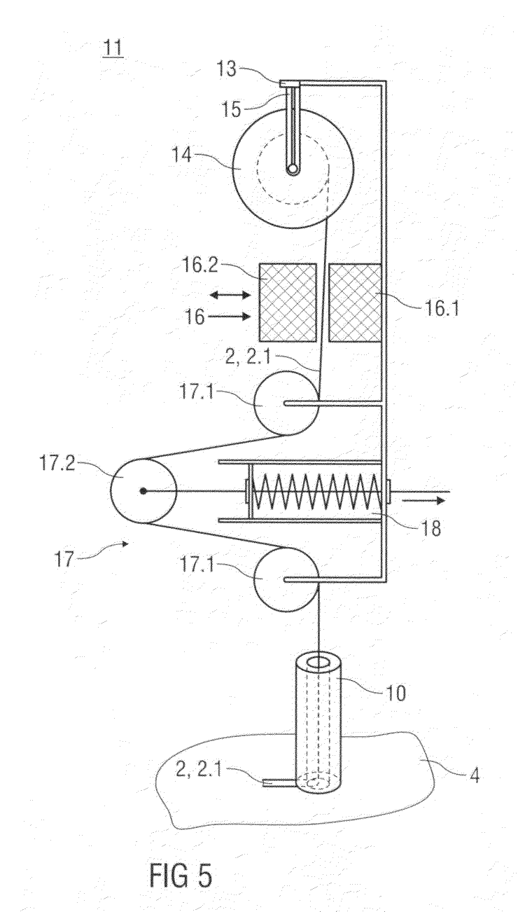

FIG. 4a A device for producing a circuit pattern in a first side view,

FIG. 4b A device for producing a circuit pattern in a further side view,

FIG. 5 A further embodiment of a device for producing a circuit pattern,

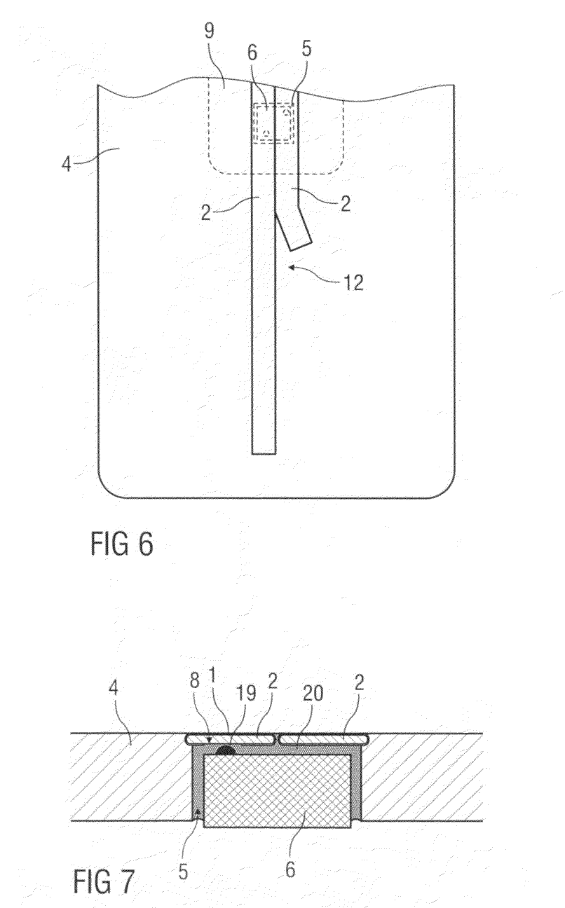

FIG. 6 A substrate with an electronic circuit formed by conductor strips and an electronic component in plan view,

FIG. 7 A cross section of the substrate with an electronic circuit formed by conductor strips and an electronic component from FIG. 6,

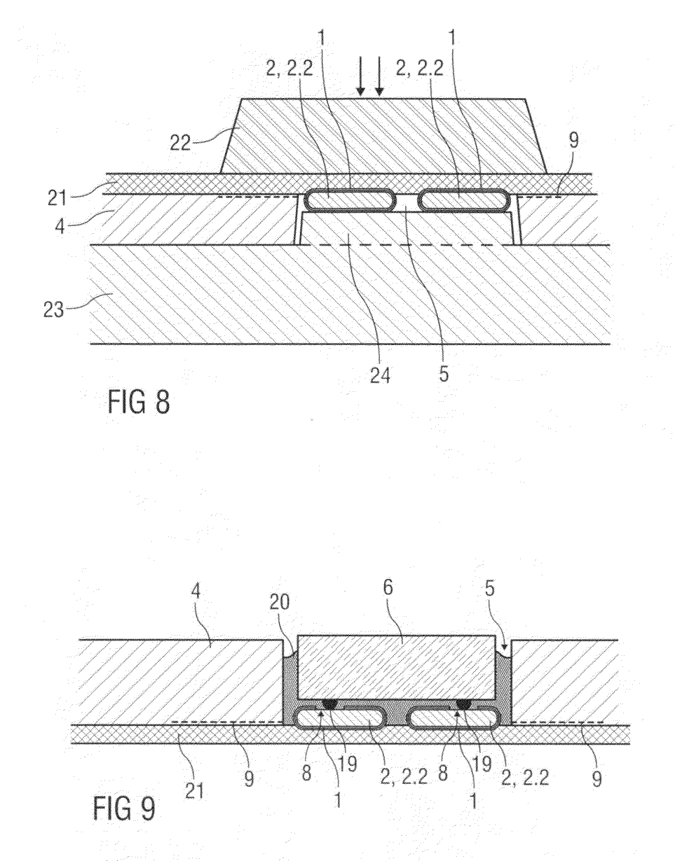

FIG. 8 A cross section through a substrate with a cover film laid in a through hole region during a partial adhering of conductor strip sections and the substrate to the cover film,

FIG. 9 A cross section through a flip chip contacted electronic component in a cast through hole of a substrate,

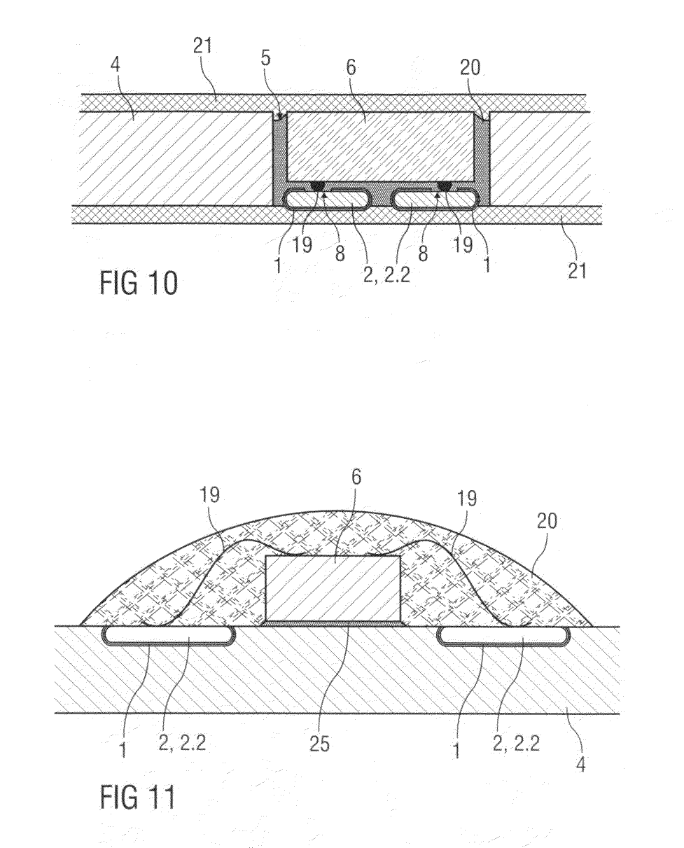

FIG. 10 A cross section of a substrate with an electronic circuit formed by conductor strips and an electronic component and two cover films,

FIG. 11A cross section through a semiconductor chip attached and cast on a substrate surface with wire connections to conductor strip sections,

FIG. 12 A cross section of a further embodiment of a substrate with an electronic circuit formed by conductor strips and an electronic component and two cover films,

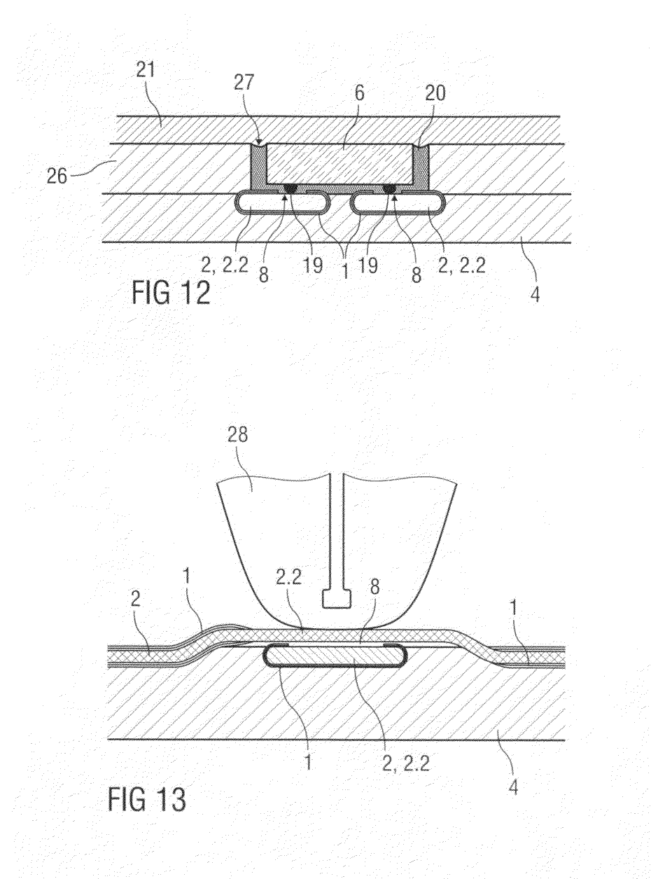

FIG. 13 A diagrammatic representation of a thermal compression contacting of a conductor strip crossing on a substrate side in cross section,

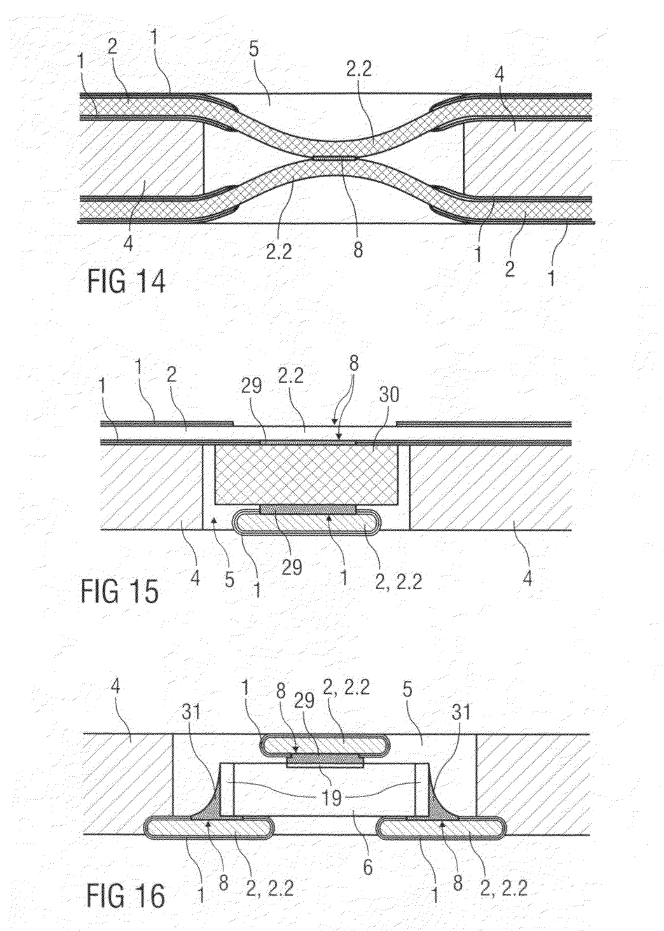

FIG. 14 A conductor strip crossing compressed in a through hole and connected by means of thermal compression welding in cross section,

FIG. 15 A conductor strip connection by means of a distance-bridging metal piece in cross section,

FIG. 16 An electronic component contacted on both sides in a through hole of a substrate in cross section, and

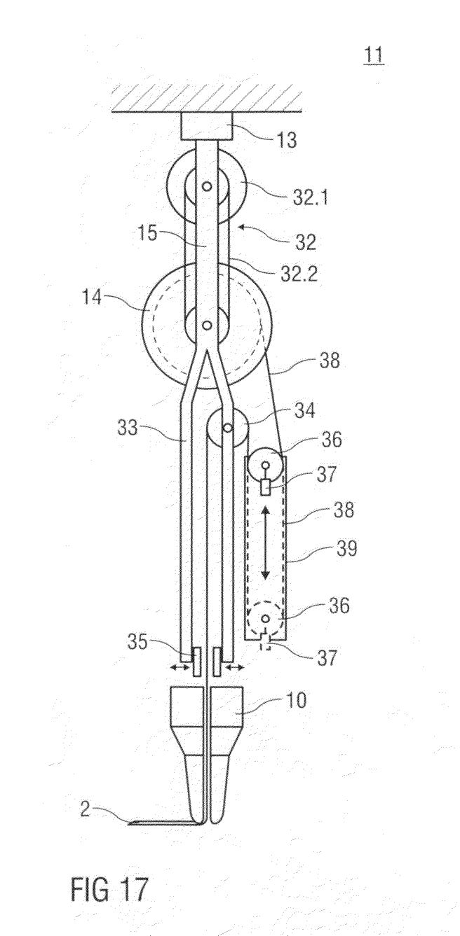

FIG. 17 A further embodiment of a device for producing a circuit pattern on a substrate.

Parts corresponding to one another are provided with the same reference numbers in all of the figures.

FIG. 1a shows a conductor strip 2 coated on all sides with an insulation varnish 1 in cross section. The conductor strip 2 is of copper or a copper alloy, for example, of copper tin bronze CuSn 6, which has a thin surface layer 3 of a precious metal. In the example shown here, this is a silver layer with a thickness of approximately 0.5 μm. The insulating varnish 1 is formed from a core varnish layer 1.1 approximately 1 μm thick with a softening temperature of greater than 240° C. and a baked varnish layer 1.2 with a thickness of approximately 3 μm and a softening temperature of greater than 130° C. The metal of the conductor strip 2 has a thickness of, for example, 7 μm and a width of 0.32 mm.

FIG. 1b shows a conductor strip cross section of the same dimension, in which the insulating varnish 1 is applied only to one surface side of the conductor strip 2. The conductor strip 2 can be attached by this surface side to a substrate 4.

FIG. 2 shows in the plan view an area part of a substrate 4 of polycarbonate 150 μm thick with a through hole 5 of a size 1.5×1.5 mm². On a lower side of the substrate 4, crossing the through hole 5, two conductor strips 2, 2.1 are located, wherein the first conductor strip 2 was produced and laid with a width which meets the requirements for the contacting and attachment of a component 6 to be mounted in the through hole 5, while a second, narrower conductor strip 2.1 in a conductor strip section 2.2 was deformed by embossing before laying to a deformation width that meets the requirements of a contacting and attachment of the electronic component 6 in this through hole 5.

With the embossing, a pattern-type embossing 7 was inserted in the conductor strip 2, 2.1 at the same time in a contacting area 8 as a routing. An edge approximately 2 mm wide around the through hole 5 represents a surrounding area 9 of the through hole 5 or of the component 6 to be mounted. The expansion of the surrounding area 9 in one direction corresponds to the length of the conductor strip section 2.2, which was deformed by embossing. The contacting areas 8 on the two conductor strips 2, 2.1 have a size of in each case of approximately 0.3×0.4 mm².

In FIG. 3 different conductor strips 2, which are laid at different depths in or on a side of the thermoplastic substrate 4, are shown in cross section. Two conductor strips 2 are not embedded in the substrate 4, a connection surface of the substrate 4 with the baked varnish layer 1.2 of the conductor strips 2 is identical to the surface of the substrate 4. The conductor strips 2 are coated with the insulating varnish 1 only on the surface side towards the substrate 4. Since the second surface side of the conductor strip 2 does not have any insulating varnish 1, contactings can be carried out on this entire surface side of the conductor strip 2. The conductor strips 2 crossing the through hole 5 are laid into the substrate 4 displacing substrate material.

It is important for the laying of conductor strips 2, 2.1 that the conductor strip 2, 2.1 is fed in a twist-free manner to a laying tool 10 of a device 11 for producing a circuit pattern 12. This is given through a suspension device 13 shown in FIGS. 4a and 4b for a conductor strip coil 14, in which a coil receptacle 15, which accommodates the conductor strip coil 14 horizontally, is pivoted about a vertical axis. By means of a tracking device (not shown) the coil receptacle 15 and thus the conductor strip coil 14 are rotated in a horizontal such that the surface of the conductor strip 2 always points in the feed direction of the laying tool 10 according to the circuit pattern 12 to be produced on the substrate 4. In FIGS. 4a and 4b two situations with different movement directions are shown. In particular in the laying of coil-like or concentric circuit patterns 12, a tracking of the coil receptacle 15 or the conductor strip coil 14 is absolutely necessary if the conductor strip 2 of the entire circuit pattern 12 is to be embedded into the substrate 4 in a twist-free manner.

FIG. 5 shows a further embodiment of the device 11 for producing the circuit pattern 12. This device comprises an embossing device 16 with a fixed anvil 16.1 and a moveable anvil 16.2 and a conductor strip guide device 17, which preferably are fixedly connected to the rotatable coil receptacle 15, so that a twist-free conductor strip guidance is guaranteed. After tangential removal of the conductor strip 2, 2.1 from the conductor strip coil 14, the conductor strip 2, 2.1 or optionally a conductor wire runs though the embossing device 16, the fixed anvil 16.1 of which and the moveable anvil 16.2 of which lie opposite one another at a short distance with parallel surfaces.

A vertical anvil length corresponds to the length of the surrounding area 9, if it is a narrow conductor strip 2.1 or conductor wire, the width of which is to be enlarged by deformation. If pattern-type embossing 7, for example, characters or reliefs, are to be embossed, a character specification or the relief determines a vertical length of the fixed anvil 16.1 and or the moveable anvil 16.2. The moveable anvil 16.2 presses with predetermined defined force the conductor strip 2.1 onto the fixed anvil 16.1 and deforms the conductor strip section 2.2 according to the vertical anvil length to the predetermined width. In the example, the anvils 16.1, 16.2 are cooled to temperatures below −10° C. in order to ensure that a water film depositing on the embossed surfaces of the anvils 16.1, 16.2 prevents the baking of the baked varnish layer 1.2 of the conductor strip section 2.2. onto the anvil surfaces 16.1, 16.2. If the embossed conductor strip section 2.2 is to have a pattern-like embossing 7, a corresponding embossed relief is to be provided in a least one of the anvils 16.1, 16.2.

Through the pressing of the anvil surfaces against one another, a removal of the conductor wire or of the conductor strip 2, 2.1 from the conductor strip coil 14 stops. The conductor strip guide device 17 with its deflection rollers 17.1 fixedly arranged and arranged one below the other in the conductor strip unrolling direction and a deflection roller 17.2 deflected horizontally to a maximum and adjustable position via a spring mounting 18 given in the example, attached to the spring mounting 18 and thus supported in a moveable manner, produces a conductor strip storage in that an increased tensile stress produced in the conductor strip 2, 2.1 or in the conductor wire by a stoppage of the conductor strip or conductor wire unrolling during the embossing of the pattern-like embossing 7 or of the conductor strip section 2.2 during further laying of the conductor strip 2, 2.1 or of the conductor wire, pushes the moveable deflection roller 17.2 against the spring mounting 18 and thus releases further conductor strip 2, 2.1 or further conductor wire for laying. After the completion of the embossing, the spring mounting 18 with the moveable deflection roller 17.2 slides back in a cushioned manner into an adjustable maximum deflection position.

A part of a card-like substrate 4 with a part of a simple laid UHF antenna as a circuit pattern 12 is shown in the plan view in FIG. 6. The circuit pattern 12 is composed of two virtually linear conductor strips 2 running in a parallel manner over the through hole 5 and the surrounding area 9 thereof and touching one another. The conductor strips 2 are coated on all sides with insulating varnish 1. The width of the conductor strip 2 is 0.4 mm. The size of the through hole 5 is 0.7×0.7 mm², and a through hole area is closed on one side by the laid conductor strips 2. The component 6 is placed into the through hole 5.

This situation is shown enlarged and in cross section in FIG. 7. The thickness of the substrate 4 of polycarbonate is 200 μm, the thickness of the conductor strip 2 is 40 μm, the thickness of the component 6, which is a semiconductor chip, is 150 μm and a height of contacts 19 of the component 6, which are formed as contact bumps, is 30 μm. The semiconductor chip has an area of 0.55×0.55 m². The component 6 is connected via both of its contacts 19 to the two contacting regions 8 of the conductor strips 2 crossing the through hole 5. A space between a surface of the component 6 with its contacts 19 and a space between the substrate 4 or between the conductor strips 2 and the component 6 is filled with a cured adhesive or potting material 20, a so-called underfiller. The substrate 4 with the inserted conductor strips 2 and the installed, contacted component 6 protected by adhesive or potting material 20 on five surfaces has only slight surface irregularities.

FIG. 8 shows the situation after the laying of the circuit pattern 12 into a side of the thermoplastic substrate 4 during a partial fixing of a first thermoplastic cover film 21 applied onto a side of the substrate 4 and the pressing of the conductor strip sections 2.2 from an open side of the through hole 5 onto the first cover film 21. A laminating stamp 22 presses the first cover film 21 in the surrounding area 9 of the through hole 5 against the substrate 4 and against the surfaces of the conductor strip sections 2.2 coated with insulating varnish 1. In the example, the surrounding area 9 of the through hole 5 is an edge 2 mm wide around the through hole 5.

In the example, the laminating stamp 22 is heated to 200° C. for the first cover film 21 of polycarbonate; a supporting table 23 and a stamp 24 inserted into the supporting table 23 and projecting into the through hole 5 are unheated or heated only to a temperature significantly below a softening point of the substrate 4 and of the first cover film 21. A laminating pressure, a temperature of the laminating stamp 22 and a laminating time are stipulated based on a thickness of the thermoplastic substrate 4 and of the first thermoplastic cover film 21 such that an adhesion of the first cover film 21 to the surface of the substrate 4 in the surrounding area 9 of the through hole 5 and to the conductor strip sections 2.2 crossing the through hole 5 results, so that the conductor strip sections 2.2 are fixed flat on the first cover film 21. Other areas of the first cover film 21 just bear on the substrate 4.

FIG. 9 shows the through hole region from FIG. 8 after the insertion of the electronic component 6 and a casting with the curable adhesive or the potting material 20 and FIG. 10 after the placement of a further first cover film 21 on the side of the substrate 4 not provided with a circuit pattern 12 and a prelamination over the entire surface of the film coating thus formed. The electronic component 6 is a semiconductor chip, the contacts 19 of which are contact bumps of gold, for example, stud bumps.

In a first step adhesive or potting material was metered into the through hole 5, which is closed on one side by the conductor strips 2 and the first cover film 21 on the side of the substrate 4 on which the circuit pattern 12 is arranged, whereby a cavity is formed, in a second step the component 6 was placed with the contacts 19 against the contacting regions 8 of the conductor strip sections 2.2 and pressed.

A type of adhesive or potting material 20 is selected such that after the placement of a further first cover film 21 onto the side of the substrate 4 without a circuit pattern 12 during the lamination of the two first cover films 21 and of the substrate with a circuit pattern 12 inserted thereon or therein and an electronic component 6 placed therein with compression of the layers and pressing caused thereby of the component 6 with its contacts 19 against the contacting regions 8, the curing of the adhesive or of the potting material 20 is carried out at laminating temperature. The contacting of the electronic component 6 and the lamination thus take place in a joint process step. In a first step, the adhesive or the potting material 20 was metered such that the cavity after insertion of the component 6 is almost completely filled. The very flat, thin prelaminate with symmetrical layers in FIG. 10 is formed by means of a procedure of this type.

A further example of the possible use of the substrate 4 provided with a circuit pattern 12 is shown in FIG. 11. A component 6, in the example shown here a semiconductor chip, is adhered by the rear side thereof directly onto the surface of the substrate 4 between two conductor strip sections 2.2 by means of a chip adhesive 25. The conductor strips 2 are coated with insulating varnish 1 only on the surface side facing towards the substrate 4. The contacts 19 of the component 6, which are electrically connected to the contacting regions 8 of the conductor strips 2, in the exemplary embodiment shown here are formed of aluminum fine wire and contacted by means of ultrasound contacting. To protect the component 6, the contacting areas 8 of the conductor strips 2 and the contacts 19 of the component 6 formed by fine wires from moisture and mechanical damage, a potting by means of adhesive or potting material 20 and a subsequent curing is used, whereby the component 6, the contacts 19 thereof and the contacting areas 8 are enclosed and protected.

FIG. 12 shows a further example of a component 6 attached and contacted on the surface of the thermoplastic substrate 4. The component 6 is provided with gold-plated contact bumps of nickel as contacts 19 and adhered by means of adhesive or potting material 20 onto the contacting areas 8, the surface of the substrate 4 and the still insulated conductor strip sections 2.2 and finally attached and contacted after the placement of a heated thermode onto the rear side of the component 6. After the placement of a second thermoplastic cover film 26 approximately the thickness of a chip, which cover film has a recess 27 in the area of the contacted component 6, and the partial lamination thereof onto the substrate 4 in a surrounding area of the recess 27, a cavity remaining around the component 6 was filled with curing adhesive or potting material 20. After the placement of the first thin thermoplastic cover film 21 onto the second cover film 26 and lamination, the prelaminate in FIG. 12 is produced.

An example of the contacting among each other of two or more circuit patterns 12 placed on one side of the substrate 4 is shown in FIG. 13. Both conductor strips 2 crossing one another are laid into the substrate 4. The conductor strip sections 2.2 bear on the surface of the substrate 4 only at a crossing connecting point. The lower conductor strip section 2.2 has a large-area contacting area 8. The upper conductor strip section 2.2. leads away over the lower conductor strip section 2.2. The situation is shown as a pulse-heated welding thermode 28 is placed on the conductor strip sections 2.2, presses them against one another and welds them to one another by means of a short welding pulse of high temperature or energy.

Some options for the connection of conductor strip sections 2.2, which are part of circuit patterns 12 that have been laid on both sides of the substrate 4, are shown in FIGS. 14 and 15. Contacting areas 8 of the conductor strips 2 are welded to one another. The welded joint in FIG. 14 can be produced very cost-effectively. The conductor strip sections 2.2 of both sides of the substrate 4 to be connected are drawn over the through hole 5, compressed in the through hole 5 and the welded joint is produced by means of pulse-heated welding thermode 28. Edges of the through hole 5 and the conductor strip sections 2.2 are deformed somewhat thereby.

A more expensive contacting of a conductor strip section 2.2 of one side of the substrate 4 with the conductor strip section 2.2 of the other side of the substrate 4 is shown in FIG. 15. Electrically conducting conductive adhesive 29 is metered onto the contacting area 8 of the conductor strip section 2.2 located below in the through hole 5, and a metal piece 30 approximately the size in area of the through hole 5 and the thickness of the substrate 4 minus the thickness of the conductor strips 2 to be contacted and located on both sides of the substrate 4, is placed into the through hole 5. Now conductive adhesive 29 is metered onto the upper side of the metal piece 30, and subsequently the upper circuit pattern 12 is laid and the conductor strip 2 to be contacted is positioned above the conductive adhesive 29. The upper conductor strip section 2.2 is thereafter stripped of insulation on both sides by means of a strong thermal pulse produced by laser radiation. After the placement of the first cover films 21 on both sides of the substrate 4, during the lamination the pressing of the conductor strips 2 onto the conductive adhesive 29 or onto the metal piece 30 and the curing of the conductive adhesive 29 producing the electrical connection of the two circuit patterns 12 take place.

A flat electronic component 6 with contacts 19 pointing to both sides of the substrate 4 in FIG. 16 was placed on two conductor strips 2 crossing the through hole 5, the contacting regions 8 of which conductor strips are provided with solder material 31, and subsequently heated such that the solder material 31 electrically and mechanically connects the contacts 19 of the electronic component 6 to the contacting regions 8 of the conductor strips 2. Conductive adhesive 29 has been metered onto the upper contact 19 of the electronic component 6.

After the laying of the circuit pattern 12 on the upper side of the substrate 44, the stripping of insulation of the planned contacting region 8 is carried out by means of a strong thermal pulse produced by laser radiation and the final contacting by placement of a thermode on the conductor strip section 2.2 above the upper contact 19 of the component 6 and the curing of the conductive adhesive 29.

FIG. 17 shows a further particularly advantageous embodiment of a device 11 for producing a circuit pattern 12 on a substrate 4, in which the conductor strip coil 14 is coupled to a drive unit 32. In the example shown here this drive unit 32 is likewise arranged on the rotatable suspension device 13 above the conductor strip coil 14 and comprises a motor 32.1 and a drive belt 32.2 for force transmission from the motor 32.1 to the conductor strip coil 14.

A holder 33 is fixedly connected to the coil receptacle 15. This holder 33 has an easily operated deflection roller 34. A conductor strip clamp 35 is arranged just above the laying tool 10 with ultrasonic oscillator, converter and sonotrode. A vertically moveable further deflection roller 36 is arranged between the deflection roller 34 and the conductor strip coil 14 and has a damper weight 37. A conductor strip reserve loop 38 can be produced by means of this further deflection roller 36.

A sensor (not shown in further detail) is attached to monitor the position/length of the conductor strip reserve loop 38 or of the further deflection roller 36. The conductor strip reserve loop 38 is located in a guide chamber 39. This is only an exemplary possibility for producing a conductor strip reserve loop 38. The motor 32.1 and thus the conductor strip coil 14 can be driven via a sensor evaluation circuit and motor drive electronics (not shown) as well as through an evaluation of a conductor strip pattern to be laid on the substrate 4 such that a sufficient conductor strip reserve loop 38 is always available.

As soon as a conductor strip pattern has been laid, the conductor strip reserve loop 38 is moved into maximum position. The conductor strip unwinding for forming the conductor strip reserve loop 38 is carried out taking into consideration the laying pattern such that the conductor strip unwinding is carried out largely continuously apart from in laying breaks. As shown here, the laying tool 10 can likewise be attached to the holder 33 and rotate with it, however a separate suspension of the laying tool 10 is to be preferred, since this renders possible better dynamics of the laying tool 10 in particular with movements perpendicular to the substrate surface, renders possible a better force control and renders possible a more uniform wear of the active area of the laying tool 10.

It is important that the conductor strip 2 falls free of kinks and without guidance over deflection edges from the deflection coil 34 into the laying tool 10. As soon as a conductor strip pattern has been laid and the laying tool 10 is to adopt a different position while lifting from the surface of the substrate, beforehand the conductor strip clamp 35 must be closed in order to prevent a drawing back of the conductor strip 2 through the vertically moveable deflection roller 36 or a change of the conductor strip position in the laying tool 10. Before laying starts, the conductor strip clamp 35 must be opened again. Through the described approach a twist-free conductor strip feed to the laying tool 10 is carried out, a predetermined and low conductor strip prestressing is obtained and the conductor strip 2 is essentially continuously unwound from the conductor strip coil 14 even at laying speeds in the range of 10 cm/s to 100 cm/s and marked changes in speed, for example, due to narrow radii or meandering patterns. This prevents the conductor strip 2 during unwinding from stretching longitudinally and thus changing its geometry, its strength and its electrical characteristic values.

### LIST OF REFERENCE NUMBERS

1 Insulating varnish
1.1 Core varnish layer
1.2 Baked varnish layer
2 Conductor strip
2.1 Narrow conductor strip
2.2 Conductor strip section
3 Surface layer of precious metal
4 Substrate
5 Through hole
6 Component
7 Pattern-like embossing
8 Contacting region
9 Surrounding region
10 Laying tool
11 Device for producing a circuit pattern
12 Circuit pattern
13 Suspension device
14 Conductor strip coil
15 Coil receptacle
16 Embossing device
16.1 Fixed anvil
16.2 Moveable anvil
17 Conductor strip guide device
17.1 Fixedly mounted deflection roller
17.2 Moveable deflection roller
18 Spring mounting
19 Contacts
20 Adhesive or potting material
21 First cover film
22 Laminating stamp
23 Supporting table
24 Stamp
25 Chip adhesive
26 Second cover film
27 Recess
28 Welding thermode
29 Conductive adhesive
30 Metal piece
31 Solder material
32 Drive unit
32.1 Motor
32.2 Drive belt
33 Holder
34 Easily operated deflection roller
35 Conductor strip clamp
36 Further deflection roller
37 Damper weight
38 Conductor strip reserve loop
39 Guide chamber

1. Circuit A circuit layout comprising:
a substrate with at least one electronic component;
at least one metallic electrically conductive conductor strip arranged on and/or in the substrate in a twist-free manner in a circuit pattern, wherein contacts of the electronic component are electrically connected to contacting regions of the conductor strip.

2. Circuit layout according to claim 1, wherein the electronic component is arranged on a surface side of the substrate (4).

3. Circuit layout according to claim 1, wherein the substrate has at least one through hole.

4. Circuit layout according to claim 3, wherein the electronic component is arranged in the through hole and/or that at least the one conductor strip spans the through hole.

5. Circuit layout according to claim 1, wherein a first cover film is arranged at least on one surface side of the substrate.

6. Method for producing a circuit pattern on a substrate, wherein at least one conductor strip is attached in a twist-free manner on at least one surface side of the substrate, which conductor strip is coated with a meltable insulating varnish at least on one surface side facing towards the substrate, wherein the insulating varnish is heated by thermal energy or by means of ultrasound and at least partially melted and the conductor strip is pressed onto the substrate in a twist-free manner.

7. Method according to claim 6, wherein before the application of the conductor strip, the substrate is pre-heated at least in one region of the circuit pattern to be produced.

8. Method according to claim 6, wherein a surface of the substrate is heated by thermal energy or by means of ultrasound and at least partially melted and the conductor strip is pressed at least partly into the substrate with displacement and/or compression of a material of the substrate.

9. Method according to claim 6, wherein the conductor strip is laid by means of a laying tool, wherein the laying tool is moved relative to the substrate and/or the substrate is moved relative to the laying tool.

10. Method according to claim 6, wherein after the laying of the conductor strip, contacting regions of the conductor strip are stripped of insulation.

11. Method according to claim 6, wherein the conductor strip or a plurality of conductor strips are applied on a surface side of the substrate crossing themselves and/or crossing one another.

12. Method according to claim 6, wherein a through hole in the substrate is closed on one side by means of a first cover film on a surface side of the substrate on which the circuit pattern is arranged, adhesive or potting material is measured into a cavity formed thereby, the electronic component is placed into the cavity and pressed with contacts against contacting regions of the conductor strip, a further first cover film is placed on a surface side of the substrate without circuit pattern and in a joint process step the two first cover films and the substrate with circuit pattern inserted thereon or therein and electronic component placed therein are laminated with compression, wherein the contacts of the electronic component are pressed against the contacting regions and contacted and the adhesive or the potting material is cured at laminating temperature.

13. Method according to claim 6, wherein conductor strips are arranged on both surface sides of the substrate and are electrically connected to one another through a through hole in the substrate.

14. Device for producing a circuit pattern on a substrate, comprising a conductor strip coil and a cylindrical or conical laying tool, which at least over a part of its length has an interior bore guiding the conductor strip and an annular active area arranged perpendicular to its longitudinal axis and merging in inner and outer radius, characterized in that the conductor strip coil is arranged in a pivoted manner about a horizontal axis of rotation in a coil receptacle, which is pivoted about a vertical axis of rotation, wherein the coil receptacle can be turned by means of a tracker device in the case of changes in direction during a laying of the conductor strip on the substrate such that the conductor strip can be unwound in a twist-free manner tangentially from the conductor strip coil.

15. Device according to claim 14, wherein the conductor strip coil is coupled to a drive unit.
